(19) United States
(12) Patent Application Publication
(10) Pub. No.: US 2024/0053398 A1
(43) Pub. Date: Feb. 15, 2024

(54) COMPOSITE TESTING MACHINE AND METHOD FOR USING COMPOSITE TESTING MACHINE

(71) Applicant: CHANGXIN MEMORY TECHNOLOGIES, INC., Hefei City, Anhui (CN)

(72) Inventor: YUNGSHIUAN CHEN, Hefei City, Anhui (CN)

(73) Assignee: CHANGXIN MEMORY TECHNOLOGIES, INC., Hefei City, Anhui (CN)

(21) Appl. No.: 17/600,413

(22) PCT Filed: Jun. 30, 2021
(86) PCT No.: PCT/CN2021/103891

§ 371 Date: Sep. 30, 2021

(30) Foreign Application Priority Data
Feb. 25, 2021 (CN) 202110215090.6

(51) Int. Cl. G01R 31/28; G11C 29/02

(52) U.S. Cl. CPC G01R 31/287; G01R 31/2874; G11C 29/022

(57) ABSTRACT

A composite testing machine includes: a burn-in test module, configured to perform a burn-in test on a sample to-be-tested in a first area; and a function test module, configured to perform a function test on the sample to-be-tested in a second area, where the second area at least partially overlaps with the first area.

### CROSS-REFERENCE TO RELATED APPLICATIONS

The present disclosure claims priority to Chinese Patent Application No. 202110215090.6, entitled “COMPOSITE TESTING MACHINE AND METHOD FOR USING COMPOSITE TESTING MACHINE”, filed to China National Intellectual Property Administration (CNIPA) on Feb. 25, 2021, which is incorporated herein by reference in its entirety.

### TECHNICAL FIELD

The present disclosure relates to, but is not limited to, a composite testing machine and a method for using a composite testing machine.

### BACKGROUND

After the integrated circuit (IC) is manufactured, it needs to go through product reliability testing to determine its performance. Product reliability testing can ensure that the factory-built IC has desirable electrical performance and an expected length of life.

Product reliability testing usually includes product life testing and product functionality testing. Product life testing is designed to test the expected life of the IC, and product functionality testing is designed to acquire the electrical performance parameters of the IC. Generally, product life testing includes a burn-in test (i.e. aging test), which implements a high-temperature and high-pressure aging process on the IC, so as to detect changes in the electrical performance parameters and circuit failures during the aging period, and further calculate the expected life of the IC.

### SUMMARY

An overview of the subject matter detailed in the present disclosure is provided below, which is not intended to limit the protection scope of the claims.

The present disclosure provides a composite testing machine and a method for using a composite testing machine.

A first aspect of the present disclosure provides a composite testing machine. The composite testing machine includes: a burn-in test module, configured to perform a burn-in test on a sample to-be-tested in a first area; and a function test module, configured to perform a function test on the sample to-be-tested in a second area, where the second area at least partially overlaps with the first area.

A second aspect of the present disclosure provides a method for using a composite testing machine. The method for using a composite testing machine includes: providing the composite testing machine described in the first aspect; providing a sample to-be-tested, and placing the sample to-be-tested in an overlapping area, to allow the burn-in test module and the function test module to test the sample to-be-tested; and starting the composite testing machine, and then testing the sample to-be-tested according to an internal program of the composite testing machine.

In the composite testing machine and the method for using composite testing machine provided by the embodiments of the present disclosure, the test area of the burn-in test module and the test area of the function test module at least partially overlap. In this way, the composite testing machine can perform the burn-in test and the function test on the sample to-be-tested in sequence without moving the sample to-be-tested. Since the sample to-be-tested does not need to be moved between the different tests, the time required for moving the sample to-be-tested is saved, and external contamination is prevented from being introduced by moving the sample to-be-tested, thereby shortening the test time and reducing external contamination.

In addition, by classifying the failure locations according to the failure causes, the distribution and comparison of the failure locations caused by different failure causes can be counted, and the root cause can be analyzed based on the statistical results so as to optimize the design and manufacture of an integrated circuit (IC).

Other aspects of the present disclosure are understandable upon reading and understanding the drawings and detailed description.

### BRIEF DESCRIPTION OF THE DRAWINGS

The drawings incorporated into the specification and constituting part of the specification illustrate the embodiments of the present disclosure, and are used together with the description to explain the principles of the embodiments of the present disclosure. In these drawings, similar reference numerals are used to represent similar elements. The drawings in the following description are part rather than all of the embodiments of the present disclosure. Those skilled in the art may derive other drawings based on these drawings without creative efforts.

FIG. 1 is a flowchart of a testing procedure of a test system.

FIG. 2 is a flowchart of a testing procedure of a composite testing machine according to an embodiment of the present disclosure.

FIG. 3 is a view illustrating a functional structure of the composite testing machine according to an embodiment of the present disclosure.

FIG. 4 is a view illustrating a temperature change of a test environment for a sample to-be-tested according to an embodiment of the present disclosure.

FIG. 5 is a flowchart of a method for using a composite testing machine according to an embodiment of the present disclosure.

### DETAILED DESCRIPTION

The technical solutions in the embodiments of the present disclosure are described below clearly and completely with reference to the drawings in the embodiments of the present disclosure. Apparently, the described embodiments are merely part rather than all of the embodiments of the present disclosure. All other embodiments obtained by those skilled in the art based on the embodiments of the present disclosure without creative efforts should fall within the protection scope of the present disclosure. It should be noted that the embodiments in the present disclosure and features in the embodiments may be combined with each other in a non-conflicting manner.

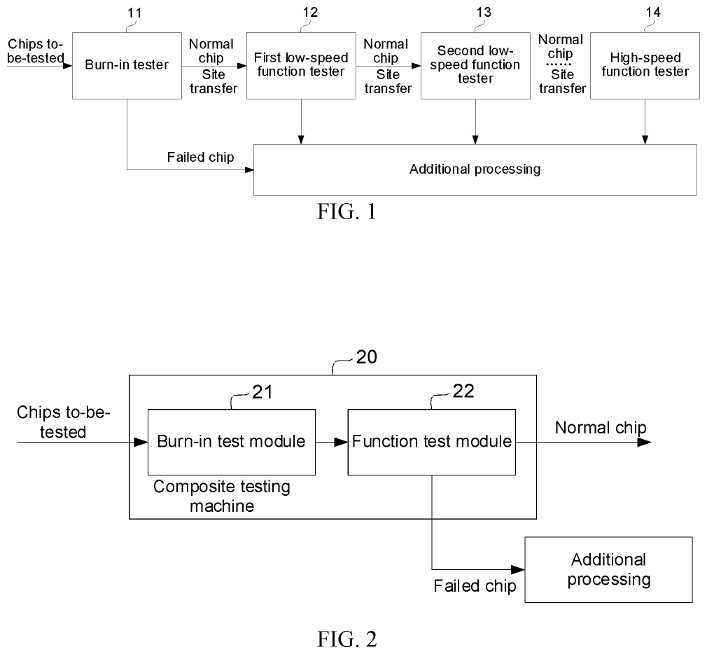

Referring to FIG. 1, a test system includes a burn-in tester 11, a first low-speed function tester 12, a second low-speed function tester 13 and a high-speed function tester 14. Chips to-be-tested first enter the burn-in tester 11 for a burn-in test. After that, the chips are transferred based on test results. That is, a normal chip is transferred to the first low-speed function tester 12, and a failed chip undergoes additional processing. By analogy, after the test of each tester is finished, the normal chip is transferred to the next tester for a corresponding life test or function test, and the failed chip is subjected to additional processing.

When normal chips are transferred between different testers, the chips need to be taken out from the current tester to check and confirm the number of the chips before they are transferred to the next tester. This process takes a lot of time, which leads to low chip test efficiency. Meanwhile, because the chips need to be taken out of the device and transferred, they are prone to external contamination, which may lead to failure or poor performance of the originally normal chips, resulting in low test accuracy or a decrease in the measured yield. In addition, in order to meet the chip testing procedure requirements of different chip development companies, different programs need to be written to execute different testing procedures, and the test program in the tester needs to be replaced within the test interval of adjacent chips, which causes a heavy workload.

Different test procedures are illustrated by the following two examples. In a first example, a test procedure prescribed by Company A includes: perform a burn-in test in the burn-in tester 11, perform a low-temperature low-speed function test in the first low-speed function tester 12, and perform a high-temperature low-speed function test in the first low-speed function tester 12. In a second example, a test procedure prescribed by Company B includes: perform a burn-in test in the burn-in tester 11, perform a high-temperature low-speed function test in the first low-speed function tester 12, and perform a low-temperature low-speed function test in the first low-speed function tester 12.

An embodiment of the present disclosure provides a composite testing machine. In this embodiment, a test area of a burn-in test module and a test area of a function test module at least partially overlap. In this way, the composite testing machine can perform a burn-in test and a function test on a sample to-be-tested in sequence without moving the sample to-be-tested. Since the sample to-be-tested does not need to be moved between the different tests, the time required for moving the sample to-be-tested is saved, and external contamination is prevented from being introduced by moving the sample to-be-tested, thereby improving the test efficiency and test accuracy.

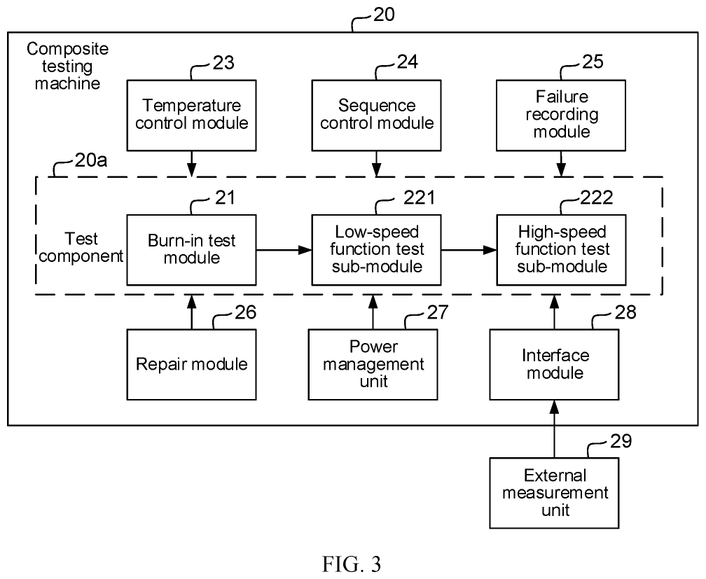

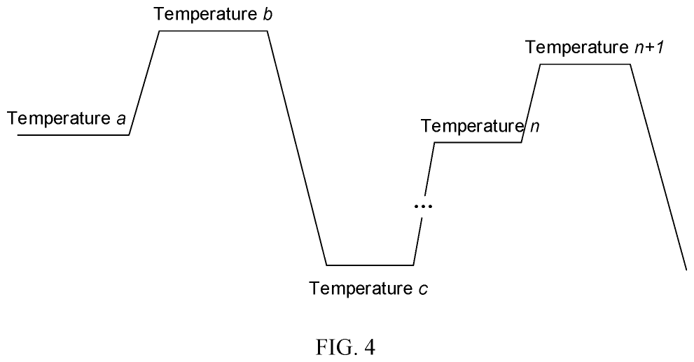

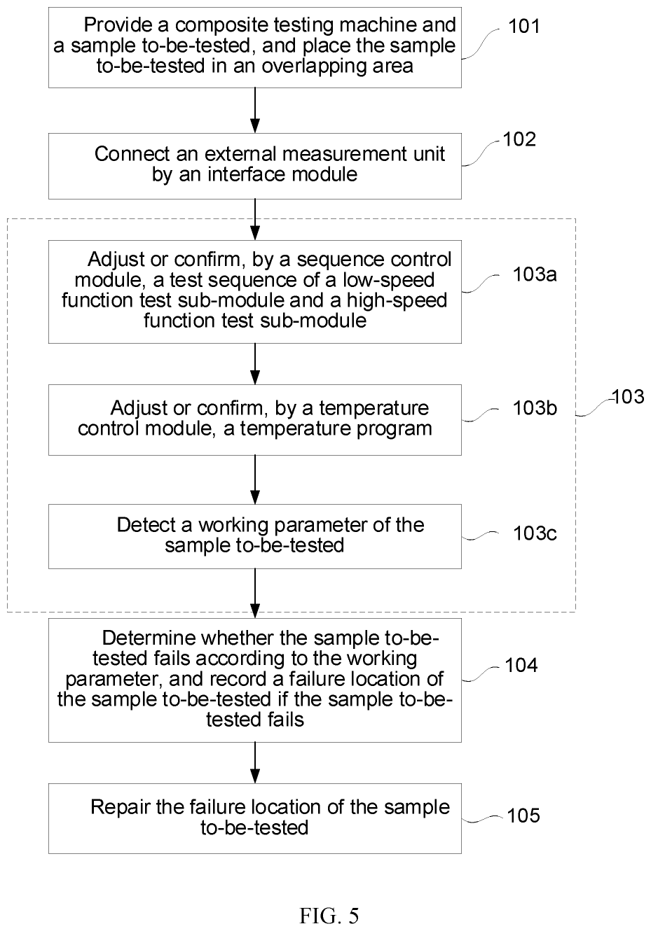

FIG. 2 is a flowchart of a testing procedure of a composite testing machine according to an embodiment of the present disclosure; FIG. 3 is a view illustrating a functional structure of the composite testing machine according to an embodiment of the present disclosure; FIG. 4 is a view illustrating a temperature change of a test environment for a sample to-be-tested according to an embodiment of the present disclosure.

As shown in FIG. 2, a composite testing machine 20 includes: a burn-in test module 21, configured to perform a burn-in test on a sample to-be-tested in a first area; and a function test module 22, configured to perform a function test on the sample to-be-tested in a second area. The second area at least partially overlaps with the first area.

The first area is a test area corresponding to the burn-in test module 21, and the second area is a test area corresponding to the function test module 22. During the burn-in test and the function test of the sample to-be-tested, the sample to-be-tested is placed in an overlapping area of the first area and the second area. After the burn-in test is completed, the function test is performed sequentially without moving the sample to-be-tested. Since there is no need to move the sample to-be-tested, the moving time required to move the sample to-be-tested is saved in the overall test time, thereby improving the test efficiency, and external contamination is prevented from being introduced, thereby improving the test yield and test accuracy of the chips to-be-tested.

In this embodiment, the burn-in test module 21 and the function test module 22 are two relatively independent hardware modules, and the test areas of the two hardware modules overlap partially or completely. In some embodiments, the burn-in test function of the burn-in test module and the function test function of the function test module are different functions of the same device. The switching of the different functions is realized by software switching. The burn-in test module and the function test module are essentially the same device, and the first area and the second area completely overlap. In some embodiments, the burn-in test module includes first hardware and general hardware, and the function test module includes second hardware and general hardware. By adjusting the general hardware to connect the first hardware or the second hardware, the switching between the burn-in test module and the function test module is realized. The first area and the second area overlap partially or completely.

In this embodiment, after the sample to-be-tested is placed in the overlapping area, the burn-in test is performed first, and then the function test is performed on normal and failed chips. After the function test is completed, normal chips are output, and failed chips are additionally processed. In other words, multiple tests are performed in the composite testing machine 20, and the failed chips are removed only after the last test is completed. The failed chips include chips that fail due to any test step. In this way, the time for taking out and counting the normal chips is saved, and the test efficiency is improved.

Referring to FIGS. 2 and 3, the composite testing machine 20 further includes a temperature control module 23. The temperature control module 23 is configured to adjust a temperature program. The temperature program includes temperature information corresponding to a time point to perform the burn-in test and the function test under a required temperature condition. The burn-in test module 21 and the function test module 22 are packaged into the same composite testing machine, and they have an overlapping test area. Therefore, the temperature program of the overlapping area can be adjusted by the temperature control module 23 to adapt to the chip testing procedure requirements of different chip development companies. There is no need to adjust the temperature program of each independent test module one by one, and there is no need to consider the temperature connection between different test steps, thereby improving the test efficiency.

In this embodiment, a test program of the burn-in test module 21 and a test program of the function test module 22 are written in the same programming language. In this way, when the temperature program of the overlapping area cannot be adjusted directly, the temperature program of different test modules can be written in the same programming language. There is no need to use multiple programming languages to write independent different temperature programs due to different programming languages of the different test modules. In addition, there is no need to consider the connection and cooperation between different temperature programs, thereby improving the test efficiency.

In this embodiment, the function test module 22 includes a low-speed function test sub-module 221 and a high-speed function test sub-module 222. The low-speed function test sub-module 221 is configured to perform a low-speed function test on the sample to-be-tested, and the high-speed function test sub-module 222 is configured to perform a high-speed function test on the sample to-be-tested. The clock rate of the chip to-be-tested in the low-speed function test is not greater than 500 MHz, and the clock rate of the chip to-be-tested in the high-speed function test is greater than 1,800 MHz, so as to accurately measure the performance parameters of the chip to-be-tested under different working conditions. Correspondingly, the clock rate of the chip to-be-tested in the burn-in test only needs to be greater than 50 MHz.

The temperature program of the low-speed function test may be different from the temperature program of the high-speed function test, or it may be different from the temperature program of the burn-in test. In fact, the temperature programs for different tests may be adjusted through the temperature control module 23 according to different needs of the chip development companies. For example, referring to FIG. 4, the temperature program of the burn-in test may be set to a constant temperature a, the temperature program of the low-speed function test may be set to temperature b and then temperature c, and the temperature program of the high-speed function test may be set to temperature n and then temperature n+1.

Referring to FIG. 3, for the sake of simplicity of the illustration and convenience of understanding, the burn-in test module 21, the low-speed function test sub-module 221 and the high-speed function test sub-module 222 are packaged and classified as a test component 20a. The test component 20a is not a substantial structure, but a category name. Other modules connected to the test component 20a, such as the temperature control module 23, are regarded as being connected to all the test modules in the test component 20a to realize corresponding functions. It should be noted that FIG. 3 only illustrates three types of test modules. In fact, there may be more types of test modules, and these test modules are all classified into the test component 20a.

In this embodiment, the function test module 22 includes multiple function test sub-modules, and the overlapping test area of the multiple function test sub-modules includes the second area. Since the second area at least partially overlaps with the first area, the second area is part of the test area of each function test sub-module. Therefore, the sample to-be-tested is placed in the overlapping area of the first area and the second area to complete the burn-in test corresponding to the burn-in test module 21 and the function test corresponding to the multiple function test sub-modules without moving the sample to-be-tested.

In this embodiment, the multiple function test sub-modules include the low-speed function test sub-module 221 and the high-speed functional test sub-module 222. The test area of the low-speed function test sub-module 221 includes the second area, and the test area of the high-speed function test sub-module 222 also includes the second area.

In this embodiment, the composite testing machine 20 further includes a sequence control module 24, configured to adjust a test sequence of the low-speed function test sub-module 221 and the high-speed function test sub-module 222. In this way, the low-speed function test or the high-speed function test may be performed first according to the needs of the chip development companies. In other embodiments, the sequence control module can adjust the test sequence of all test modules. For example, the low-speed function test, the burn-in test and the high-speed function test may be performed in sequence.

It should be noted that if the way to switch between different test modules is to switch between different software or different programs in the same software, the sequence control module 24 is configured to adjust the switching sequence of the software or programs. If the way to switch between different test modules is to switch hardware or switch the connection relationship, the sequence control module 24 is configured to switch the application sequence of the hardware or switch the connection relationship.

In this embodiment, the composite testing machine 20 further includes: a failure recording module 25, configured to record a failure location of the sample to-be-tested during the burn-in test and the function test. Recording the failure location has two functions. First, it is convenient to repair the failure location so as to transform the failed chip into a normal chip. Second, it is easy to summarize. That is, according to the test results of multiple chips to-be-tested, the locations of chips that are prone to failure and the distribution of the failure locations are counted, and the analysis is fed back to the chip design and manufacturing departments, so as to optimize chip quality and improve chip yield.

In this embodiment, the failure recording module is further configured to detect a failure cause at the failure location, and then classify the failure location according to the failure cause. By classifying the failure locations according to the failure causes, the distribution and comparison of the failure locations caused by different failure causes can be counted, and the root cause can be analyzed based on the statistical results so as to optimize the design and manufacture of an integrated circuit (IC).

The failure cause includes any one or any combination of a single storage bit failure, a connected storage bits failure, a single word line failure and a connected word lines failure.

In this embodiment, the composite testing machine 20 further includes a repair module 26, configured to repair the failure location. Specifically, the chip to-be-tested includes a spare bit. If a failed bit is found during or after a certain test step, the structure of a connection line can be changed by the fusing of a fuse, such that a non-failed part of the failed chip is connected to the spare bit. That is, the spare bit is used to replace the failed bit in the failure location, so as to achieve the purpose of repairing the failure location and repairing the failed chip. After the repair, the current test or all the tests that have been performed need to be re-run to ensure the repair is successful.

In this embodiment, the composite testing machine 20 further includes a power management unit 27, configured to provide a voltage excitation signal or a current excitation signal to the sample to-be-tested in the burn-in test and the function test, and measure a working voltage or working current of the sample to-be-tested. By providing the voltage excitation signal or the current excitation signal to the sample to-be-tested under the test condition, the sample to-be-tested can be controlled to be in a rated operating state or a full load state, so as to accelerate the occurrence of defects in the chip to-be-tested under the operating state. In addition, by measuring the working parameters of the chip to-be-tested, it can be determined whether the chip to-be-tested has a failure, and the failure location of the chip to-be-tested can be determined.

In other embodiments, a temperature sensor may also be used to measure the working parameter such as the temperature or working frequency of the chip to-be-tested, so as to determine whether the chip to-be-tested has a failure and determine the failure location of the chip to-be-tested, thereby improving the test accuracy.

In this embodiment, the composite testing machine 20 further includes: an interface module 28, configured to connect to an external measurement unit 29, for example, an oscilloscope. The external measurement unit 29 is configured to detect the working parameter of the sample to-be-tested. The working parameter includes working voltage, working current or working frequency. In this way, the test condition of the chip to-be-tested can be monitored through the external measurement unit when there is no internal measurement unit or the internal measurement unit is unavailable.

In this embodiment, the test area of the burn-in test module and the test area of the function test module at least partially overlap. In this way, the composite testing machine can perform the burn-in test and the function test on the sample to-be-tested in sequence without moving the sample to-be-tested. Since the sample to-be-tested does not need to be moved between the different tests, the time required for moving the sample to-be-tested is saved, and external contamination is prevented from being introduced by moving the sample to-be-tested, thereby shortening the test time and reducing external contamination.

An embodiment of the present disclosure further provides a method for using a composite testing machine, which is used for the composite testing machine according to any one of the above descriptions.

Referring to FIGS. 3 and 5, the method for using a composite testing machine includes the following steps:

Step 101: Provide the composite testing machine 20 and a sample to-be-tested, and place the sample to-be-tested in an overlapping area.

The overlapping area is an overlapping part of the first area and the second area. The sample to-be-tested is placed in the overlapping area, so as to allow the burn-in test module 21 and the function test module 22 to test the sample to-be-tested.

Step 102: Connect an external measurement unit 29 by the interface module 28.

In this embodiment, before the composite testing machine 20 is started, the external measurement unit 29 is connected. The external measurement unit 29 is configured to measure a working parameter of the sample to-be-tested. The working parameter includes any one or any combination of working voltage, working current and working frequency. In other embodiments, an internal measurement unit is provided in the composite testing machine, and the working parameter of the sample to-be-tested is directly measured by the internal measurement unit. In this case, Step 102 can be skipped and Step 103 is performed directly.

Step 103: Start the composite testing machine 20, and then test the sample to-be-tested according to an internal program of the composite testing machine 20.

In this embodiment, the function test module 22 includes a low-speed function test sub-module 221 and a high-speed function test sub-module 222. Step 103 includes a first sub-step 103a: adjust or confirm, by the sequence control module 24, a test sequence of the low-speed function test sub-module 221 and the high-speed function test sub-module 222.

In this embodiment, Step 103 further includes a second sub-step 103b: adjust or confirm, by the temperature control module 23, a temperature program. The temperature program includes temperature information corresponding to a time point to perform the burn-in test and the function test under a required temperature condition. The step of adjusting or confirming the temperature program may be performed before adjusting the test sequence, or after adjusting the test sequence.

After the first sub-step 103a and the second sub-step 103b are executed, a third sub-step 103c is executed: detect the working parameter of the sample to-be-tested. The detection action may be executed by the external measurement unit 29 or the internal measurement unit.

Step 104: Determine whether the sample to-be-tested fails according to the working parameter, and record the failure location of the sample to-be-tested if the sample to-be-tested fails. The step of recording the failure location of the sample to-be-tested includes: determine a failure cause at the failure location according to the working parameter, and then classify the failure location according to the failure cause.

Step 105: Repair the failure location of the sample to-be-tested.

In this embodiment, by testing the sample to-be-tested by the above method for using a composite testing machine, the transfer and counting time of the sample to-be-tested is saved, and external contamination is prevented from being introduced, thereby improving the test efficiency and test accuracy.

Each embodiment or implementation in the specification of the present disclosure is described in a progressive manner. Each embodiment focuses on the difference from other embodiments, and the same and similar parts between the embodiments may refer to each other.

In the description of the specification, the description with reference to terms such as “an embodiment”, “an illustrative embodiment”, “some implementations”, “an illustrative implementation” and “an example” means that the specific feature, structure, material or feature described in combination with the implementation(s) or example(s) is included in at least one implementation or example of the present disclosure.

In this specification, the schematic expression of the above terms does not necessarily refer to the same implementation or example. Moreover, the described specific feature, structure, material or characteristic may be combined in an appropriate manner in any one or more implementations or examples.

It should be noted that in the description of the present disclosure, the terms such as “center”, “top”, “bottom”, “left”, “right”, “vertical”, “horizontal”, “inner” and “outer” indicate the orientation or position relationships based on the drawings. These terms are merely intended to facilitate description of the present disclosure and simplify the description, rather than to indicate or imply that the mentioned device or element must have a specific orientation and must be constructed and operated in a specific orientation. Therefore, these terms should not be construed as a limitation to the present disclosure.

It should be understood that the terms such as “first” and “second” used herein may be used to describe various structures, but these structures are not limited by these terms. Instead, these terms are merely intended to distinguish one element from another.

The same elements in one or more drawings are denoted by similar reference numerals. For the sake of clarity, various parts in the drawings are not drawn to scale. In addition, some well-known parts may not be shown. For the sake of brevity, the structure obtained by implementing multiple steps may be shown in one figure. In order to make the understanding of the present disclosure more clearly, many specific details of the present disclosure, such as the structure, material, size, processing process and technology of the device, are described below. However, as those skilled in the art can understand, the present disclosure may not be implemented according to these specific details.

Finally, it should be noted that the above embodiments are merely intended to explain the technical solutions of the present disclosure, rather than to limit the present disclosure. Although the present disclosure is described in detail with reference to the above embodiments, those skilled in the art should understand that they may still modify the technical solutions described in the above embodiments, or make equivalent substitutions of some or all of the technical features recorded therein, without deviating the essence of the corresponding technical solutions from the scope of the technical solutions of the embodiments of the present disclosure.

### INDUSTRIAL APPLICABILITY

In the composite testing machine and the method for using composite testing machine provided by the embodiments of the present disclosure, the test area of the burn-in test module and the test area of the function test module at least partially overlap. In this way, the composite testing machine can perform the burn-in test and the function test on the sample to-be-tested in sequence without moving the sample to-be-tested. Since the sample to-be-tested does not need to be moved between the different tests, the time required for moving the sample to-be-tested is saved, and external contamination is prevented from being introduced by moving the sample to-be-tested, thereby shortening the test time and reducing external contamination. In addition, by classifying the failure locations according to the failure causes, the distribution and comparison of the failure locations caused by different failure causes can be counted, and the root cause can be analyzed based on the statistical results so as to optimize the design and manufacture of an IC.

1. A composite testing machine, comprising:
a burn-in test module, configured to perform a burn-in test on a sample to-be-tested in a first area; and
a function test module, configured to perform a function test on the sample to-be-tested in a second area, wherein the second area at least partially overlaps with the first area.

2. The composite testing machine according to claim 1, wherein the composite testing machine further comprises: a temperature control module; the temperature control module is configured to adjust a temperature program; the temperature program comprises temperature information corresponding to a time point to perform the burn-in test and the function test under a required temperature condition.

3. The composite testing machine according to claim 1, wherein a test program of the burn-in test module and a test program of the function test module are written in a same programming language.

4. The composite testing machine according to claim 1, wherein the function test module comprises a low-speed function test sub-module and a high-speed function test sub-module; the low-speed function test sub-module is configured to perform a low-speed function test on the sample to-be-tested, and the high-speed function test sub-module is configured to perform a high-speed function test on the sample to-be-tested.

5. The composite testing machine according to claim 4, wherein a test area of the low-speed function test sub-module comprises the second area, and a test area of the high-speed function test sub-module comprises the second area.

6. The composite testing machine according to claim 4, wherein the composite testing machine further comprises: a sequence control module; the sequence control module is configured to adjust a test sequence of the low-speed function test sub-module and the high-speed function test sub-module.

7. The composite testing machine according to claim 1, wherein the composite testing machine further comprises: a failure recording module; the failure recording module is configured to record a failure location of the sample to-be-tested during the burn-in test and the function test.

8. The composite testing machine according to claim 7, wherein the failure recording module is further configured to detect a failure cause at the failure location, and then classify the failure location according to the failure cause.

9. The composite testing machine according to claim 8, wherein the failure cause comprises any one or any combination of a single storage bit failure, a connected storage bits failure, a single word line failure and a connected word lines failure.

10. The composite testing machine according to claim 7, wherein the composite testing machine further comprises: a repair module; the repair module is configured to repair the failure location.

11. The composite testing machine according to claim 1, wherein the composite testing machine further comprises: a power management unit; the power management unit is configured to provide a voltage excitation signal or a current excitation signal to the sample to-be-tested in the burn-in test and the function test, and measure a working voltage or working current of the sample to-be-tested.

12. The composite testing machine according to claim 1, wherein the composite testing machine further comprises: an interface module; the interface module is configured to connect to an external measurement unit; the external measurement unit is configured to measure a working parameter of the sample to-be-tested; the working parameter comprises working voltage, working current or working frequency.

13. A method for using a composite testing machine, comprising:
providing the composite testing machine, wherein the composite testing machine comprises a burn-in test module, and a function test module; the burn-in test module is configured to perform a burn-in test on a sample to-be-tested in a first area; the function test module is configured to perform a function test on the sample to-be-tested in a second area; the second area at least partially overlaps with the first area;
providing a sample to-be-tested, and placing the sample to-be-tested in an overlapping area to allow the burn-in test module and the function test module to test the sample to-be-tested; and
starting the composite testing machine, and then testing the sample to-be-tested according to an internal program of the composite testing machine.

14. The method for using a composite testing machine according to claim 13, wherein the function test module comprises: a low-speed function test sub-module, and a high-speed function test sub-module;
the step of starting the composite testing machine comprises: adjusting or confirming, by a sequence control module, a test sequence of the low-speed function test sub-module and the high-speed function test sub-module.

15. The method for using a composite testing machine according to claim 13, wherein the step of starting the composite testing machine comprises: adjusting or confirming, by a temperature control module, a temperature program; the temperature program comprises temperature information corresponding to a time point to perform the burn-in test and the function test under a required temperature condition.

16. The method for using a composite testing machine according to claim 13, wherein before starting the composite testing machine, the method for using a composite testing machine further comprises: connecting, by an interface module, an external measurement unit; the external measurement unit is configured to measure a working parameter of the sample to-be-tested; the working parameter comprises any one or any combination of working voltage, working current and working frequency.

17. The method for using a composite testing machine according to claim 13, wherein the step of testing the sample to-be-tested comprises: detecting a working parameter of the sample to-be-tested during the burn-in test and the function test, and determining whether the sample to-be-tested fails according to the working parameter; and recording a failure location of the sample to-be-tested if the sample to-be-tested fails.

18. The method for using a composite testing machine according to claim 17, wherein the step of recording a failure location of the sample to-be-tested comprises: determining a failure cause at the failure location according to the working parameter, and then classifying the failure location according to the failure cause.

19. The method for using a composite testing machine according to claim 17, wherein, if the sample to-be-tested fails, the method for using a composite testing machine further comprises: repairing the failure location of the sample to-be-tested.
